(19) United States
(12) Patent Application Publication
(10) Pub. No.: US 2025/0098262 A1
(43) Pub. Date: Mar. 20, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Kouta TOMITA, Nonoichi Ishikawa (JP)

(21) Appl. No.: 18/443,729

(22) Filed: Feb. 16, 2024

(30) Foreign Application Priority Data
Sep. 14, 2023 (JP) 2023-149480

(51) Int. Cl. H01L 29/40; H01L 29/06; H01L 29/78

(52) U.S. Cl. CPC H10D 64/117; H10D 30/668; H10D 62/127; H10D 84/146

(57) ABSTRACT

A semiconductor device includes a first electrode, a first semiconductor layer, a second semiconductor layer, a third semiconductor layer, a second electrode, a third electrode, and a fourth electrode. The third electrode is arranged along a boundary between adjacent regions of the plurality of regions. The third electrode is not located at a portion of the boundary most distant to the second electrode. The third electrode faces the second semiconductor layer via an insulating body. The fourth electrode is located on the third semiconductor layer. The fourth electrode is connected to the second semiconductor layer, the third semiconductor layer, and the second electrode. A portion of the fourth electrode located at the most distant portion has a Schottky barrier junction with the first semiconductor layer.

### CROSS-REFERENCE TO RELATED APPLICATIONS

This application is based upon and claims the benefit of priority from Japanese Patent Application No. 2023-149480, filed on Sep. 14, 2023; the entire contents of which are incorporated herein by reference.

### FIELD

Embodiments described herein relate generally to a semiconductor device.

### BACKGROUND

A semiconductor device for power control has been proposed in which columnar field plate electrodes (hereinbelow, also called “FP electrodes”) are periodically arranged, and a gate electrode is located between the FP electrodes. It is desirable to increase the breakdown voltage and reduce the on-resistance of such a semiconductor device.

### BRIEF DESCRIPTION OF THE DRAWINGS

FIG. 1 is a plan view showing a semiconductor device according to an embodiment;

FIG. 2 is a cross-sectional view along line A-A′ shown in FIG. 1;

FIG. 3 is a cross-sectional view along line B-B′ shown in FIG. 1;

FIG. 4 is a partially enlarged cross-sectional view showing region C of FIG. 3; and

FIG. 5 is a plan view showing a semiconductor device according to a comparative example.

### DETAILED DESCRIPTION

In general, according to one embodiment, a semiconductor device includes a first electrode, a first semiconductor layer, a second semiconductor layer, a third semiconductor layer, a second electrode, a third electrode, and a fourth electrode. The first semiconductor layer is located on the first electrode. The first semiconductor layer includes a plurality of regions. The first semiconductor layer is connected to the first electrode. The first semiconductor layer is of a first conductivity type. The second semiconductor layer is located on the first semiconductor layer. The second semiconductor layer is of a second conductivity type. The third semiconductor layer is located on a portion of the second semiconductor layer. The third semiconductor layer is of the first conductivity type. The second electrode is located in each of the plurality of regions. The second electrode faces the first semiconductor layer via an insulating body. The third electrode is arranged along a boundary between adjacent regions of the plurality of regions. The third electrode is not located at a portion of the boundary most distant to the second electrode. The third electrode faces the second semiconductor layer via an insulating body. The fourth electrode is located on the third semiconductor layer. The fourth electrode is connected to the second semiconductor layer, the third semiconductor layer, and the second electrode. A portion of the fourth electrode located at the most distant portion has a Schottky barrier junction with the first semiconductor layer.

### Embodiment

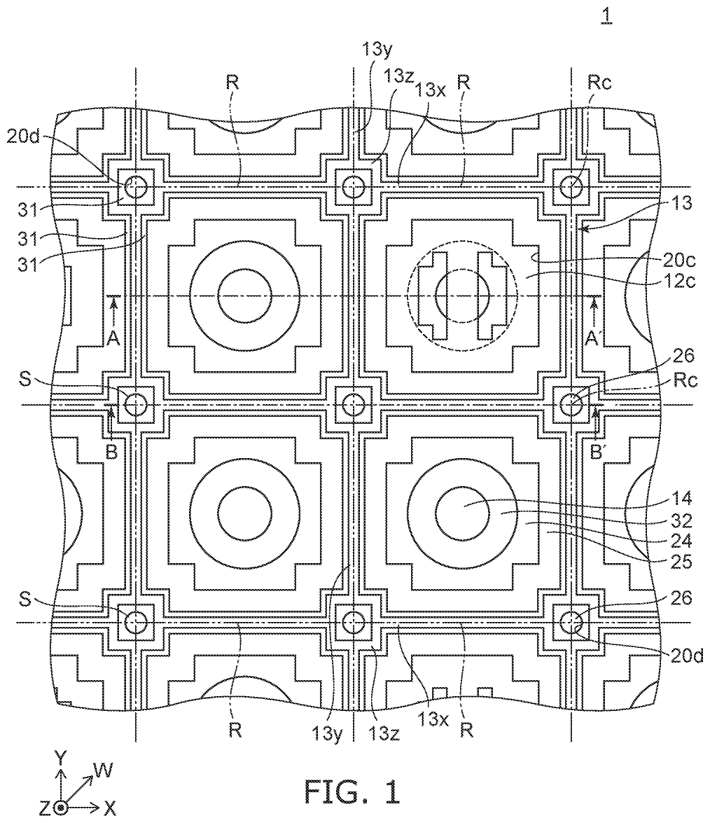

FIG. 1 is a plan view showing a semiconductor device according to the embodiment.

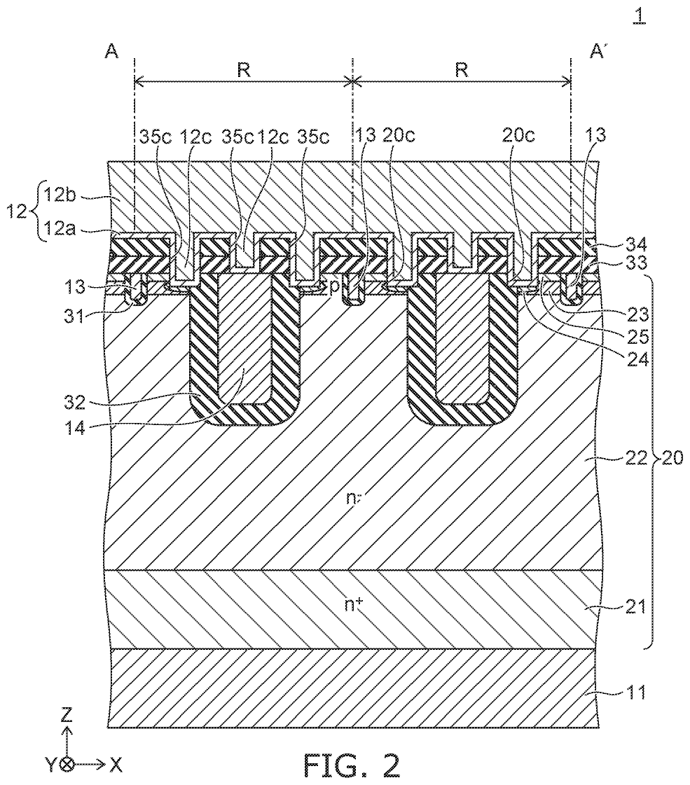

FIG. 2 is a cross-sectional view along line A-A′ shown in FIG. 1.

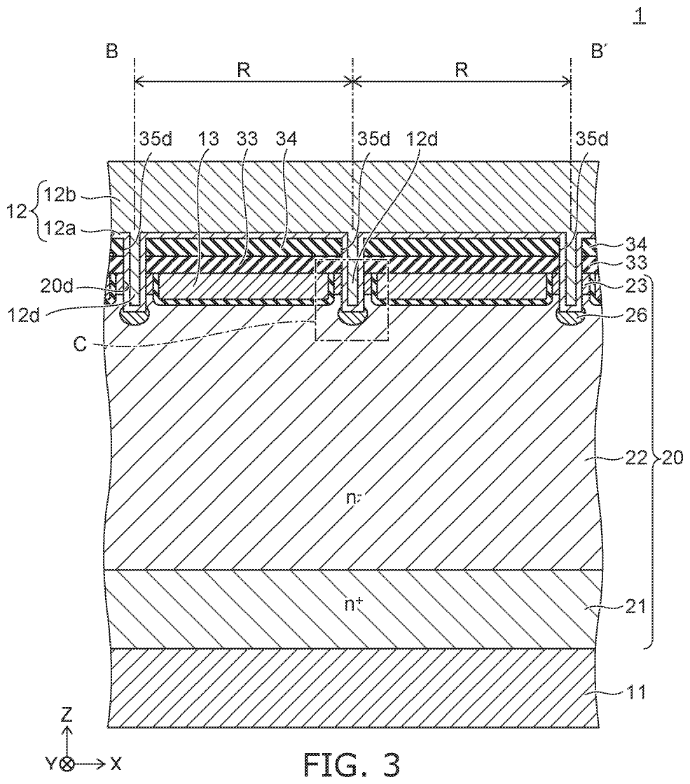

FIG. 3 is a cross-sectional view along line B-B′ shown in FIG. 1.

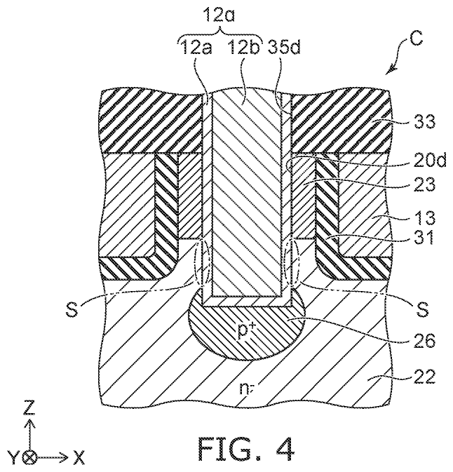

FIG. 4 is a partially enlarged cross-sectional view showing region C of FIG. 3.

The drawings are schematic, and are enhanced and simplified as appropriate.

As shown in FIGS. 1 to 4, the semiconductor device 1 according to the embodiment includes a drain electrode 11 (a first electrode), a source electrode 12 (a fourth electrode), a gate electrode 13 (a third electrode), a FP electrode 14 (a second electrode), and a semiconductor part 20. The semiconductor part 20 is made of a semiconductor material, e.g., single-crystal silicon (Si); and the prescribed conductivity type and carrier concentration is realized at each portion by introducing an impurity. The semiconductor device 1 also includes a gate insulating film 31, a FP insulating film 32, and inter-layer insulating films 33 and 34.

The drain electrode 11 is located on the entire lower surface of the semiconductor part 20. The inter-layer insulating film 33 is located on the semiconductor part 20. The inter-layer insulating film 34 is located on the inter-layer insulating film 33. Openings 35c and 35d are formed in the inter-layer insulating films 33 and 34. The source electrode 12 is located on the inter-layer insulating film 34.

Multiple regions R having the same shape are set at the upper surface of the semiconductor part 20 and are gaplessly packed. The shape of the region R is, for example, a square when viewed from above. The multiple square regions R are arranged in a matrix configuration when viewed from above.

A recess 20c is formed inside each region R at the upper surface of the semiconductor part 20. A recess 20d is formed at the corners of each region R, i.e., the portions at which four regions R contact each other. The recess 20c is located in the region directly under the opening 35c. The recess 20d is located in the region directly under the opening 35d.

In the specification, an XYZ orthogonal coordinate system is employed for convenience of description. The direction from the drain electrode 11 toward the source electrode 12 is taken as a “Z-direction”; and two directions in which the regions R are arranged are taken as an “X-direction” (a first direction) and a “Y-direction” (a second direction). Although the Z-direction also is called “up/above/higher than”, and the opposite direction of the Z-direction also is called “down/below/lower than”, these expressions are for convenience and are independent of the direction of gravity.

The source electrode 12 includes a lower layer 12a (a first metal layer), and an upper layer 12b (a second metal layer) located on the lower layer 12a. The lower layer 12a includes, for example, at least one type of metal selected from the group consisting of titanium (Ti), nickel (Ni), platinum (Pt), and tungsten (W). The upper layer 12b includes, for example, at least one type of metal selected from the group consisting of aluminum (Al) and copper (Cu).

The source electrode 12 also is located inside the openings 35c and 35d formed in the inter-layer insulating films 33 and 34 and inside the recesses 20c and 20d formed at the upper surface of the semiconductor part 20. The portion of the source electrode 12 located in the opening 35c and in the recess 20c is called a “source contact 12c”; and the portion of the source electrode 12 located in the opening 35d and in the recess 20d is called a “source contact 12d”. For easier viewing of the drawing in FIG. 1, only one source contact 12c is shown, and the other portions of the source electrode 12 are not illustrated.

The gate electrode 13 and the FP electrode 14 are located in the semiconductor part 20. The gate insulating film 31 covers the lower surface and side surface of the gate electrode 13. As a result, the gate electrode 13 is insulated from the semiconductor part 20. The upper surface of the gate electrode 13 is covered with the inter-layer insulating film 33. As a result, the gate electrode 13 is insulated from the source electrode 12. The FP insulating film 32 covers the lower surface and side surface of the FP electrode 14. As a result, the FP electrode 14 is insulated from the semiconductor part 20. The lower end of the FP electrode 14 is positioned lower than the lower end of the gate electrode 13. The average thickness of the FP insulating film 32 is greater than the average thickness of the gate insulating film 31.

The gate electrode 13 is arranged along the boundary of the multiple regions R when viewed from above, i.e., the Z-direction. The shape of the gate electrode 13 is substantially a lattice shape when viewed from above. In other words, the gate electrode 13 includes a portion 13x extending in the X-direction and a portion 13y extending in the Y-direction.

However, at the lattice crossing points, i.e., the positions at which the four regions R contact each other, a frame-shaped portion 13z is provided, and the portion 13x and the portion 13y are not provided. The shape of the frame-shaped portion 13z when viewed from above is, for example, a square frame shape. The portion 13x and the portion 13y each contact the frame-shaped portion 13z; and the portion 13x and the portion 13y do not contact each other. In other words, the gate electrode 13 is arranged along the boundary of the multiple regions R but is not located at the corners of the regions R.

The gate electrode 13 is formed to have a continuous body made of the portion 13x, the portion 13y, and the frame-shaped portion 13z, and is connected to a gate pad (not illustrated) located on the inter-layer insulating film 34. In the specification, “connected” means an electrical connection.

When viewed from above, the FP electrodes 14 are located respectively at the vicinities of the centers of the regions R. The shape of the FP electrode 14 is substantially a circular pillar shape having a central axis extending in the Z-direction. The upper surface of the FP electrode 14 is connected to the source contact 12c. The gate electrode 13 surrounds the FP electrodes 14 when viewed from above. The corners of the regions R are portions Rc of the boundary of the multiple regions R most distant to the FP electrodes 14. The portions Rc are positioned in the frame-shaped portions 13z.

The semiconductor part 20 includes a drain layer 21, a drift layer 22, a base layer 23, a base contact layer 24, a source layer 25 (a third semiconductor layer), and a contact layer 26 (a fourth semiconductor layer).

The drain layer 21 is located on the drain electrode 11 and connected to the drain electrode 11. The conductivity type of the drain layer 21 is the n⁺-type. The drift layer 22 is located on the drain layer 21 and contacts the drain layer 21. The conductivity type of the drift layer 22 is the n⁻-type. The “n⁺-type” refers to a higher carrier concentration than the “n-type”; and the “n⁻-type” refers to a lower carrier concentration than the “n-type”. This is similar for the p-type as well. A first semiconductor layer is formed of the drain layer 21 and the drift layer 22.

The base layer 23 is located on the drift layer 22 and contacts the drift layer 22. The conductivity type of the base layer 23 is the p-type. The base contact layer 24 is located on a portion of the base layer 23 in a region directly under the recess 20c. The conductivity type of the base contact layer 24 is the p⁺-type. A second semiconductor layer is formed of the base layer 23 and the base contact layer 24.

The source layer 25 is located on another portion of the base layer 23. The source layer 25 is arranged along the gate insulating film 31. The lower surface of the source layer 25 contacts the base layer 23; the upper surface of the source layer 25 contacts the inter-layer insulating film 33; and the side surface of the source layer 25 contacts the gate insulating film 31 and the source contact 12c. The conductivity type of the source layer 25 is the n⁺-type.

When viewed from above, the contact layer 26 is located at the portion Rc, i.e., the corner of the region R, and is located in the region directly under the recess 20d of the semiconductor part 20. The contact layer 26 contacts the source contact 12d at the bottom surface of the recess 20d. The contact layer 26 also contacts the drift layer 22 and the base layer 23. The conductivity type of the contact layer 26 is the p⁺-type.

The gate electrode 13 faces the source layer 25, the base layer 23, and the upper portion of the drift layer 22 via the gate insulating film 31. As a result, an inversion layer can be formed in the region of the base layer 23 that contacts the gate insulating film 31. As a result, a MOSFET is realized in the semiconductor device 1.

The FP electrode 14 is located in the region R when viewed from above, and faces the base contact layer 24, the base layer 23, and the upper portion of the drift layer 22 via the FP insulating film 32. As a result, the charge of ionized donors in the drift layer 22 can be compensated, so that the carrier concentration of the drift layer 22 can be increased, the breakdown voltage between the source and drain of the semiconductor device 1 can be increased, and the on-resistance can be reduced.

The multiple FP electrodes 14 and the multiple contact layers 26 are alternately arranged along a W-direction (a third direction), which crosses the X-direction and the Y-direction and is parallel to the XY-plane including the X-direction and Y-direction. When the shape of the region R is a square, the W-direction is tilted 45° with respect to the X-direction and Y-direction.

A portion of the side surface of the source contact 12d contacts the drift layer 22 at the lower portion of the side surface of the recess 20d. As a result, the lower layer 12a of the source electrode 12 has a Schottky barrier junction with the drift layer 22. As a result, when viewed from above, a Schottky barrier diode S is realized at the portion Rc.

Operations of the embodiment will now be described.

In the semiconductor device 1 according to the embodiment as shown in FIG. 1, the FP electrode 14 is located at the center of each region R. Because the FP electrode 14 compensates the charge of ionized donors in the drift layer 22, the carrier concentration of the drift layer 22 can be increased, the breakdown voltage of the semiconductor device 1 can be increased, and the on-resistance can be reduced.

According to the embodiment, at the portion Rc of the boundary of the regions R most distant to the FP electrode 14, i.e., at the corner of the regions R, the source contact 12d is provided without providing the gate electrode 13. The lower layer 12a of the source contact 12d is formed of a material that forms a Schottky barrier junction with the drift layer 22. As a result, the source contact 12d of the source electrode 12 located at the portion Rc has a Schottky barrier junction with the drift layer 22. As a result, the Schottky barrier diode S can be realized at the portion Rc.

Effects of the embodiment will now be described.

According to the embodiment, by providing the source contact 12d at the portion Rc of the boundary of the regions R most distant to the FP electrode 14, a reduction of the breakdown voltage at the portion Rc can be avoided, and the breakdown voltage of the semiconductor device 1 can be increased. In other words, the carrier concentration of the drift layer 22 can be improved and the on-resistance can be reduced while ensuring the required breakdown voltage of the semiconductor device 1.

Generally, the increase of the breakdown voltage and the reduction of the on-resistance have a trade-off relationship; however, according to the embodiment, the balance of the two can be improved. Therefore, according to the required characteristics of the semiconductor device 1, the breakdown voltage can be increased while maintaining a constant on-resistance; the on-resistance can be reduced while maintaining a constant breakdown voltage; or both the increase of the breakdown voltage and the reduction of the on-resistance can be realized.

In the semiconductor device 1, a SBD is located at the portion Rc. The SBD has a lower forward voltage than a p-n junction diode, and so the recovery loss (Qrr) of the parasitic diode can be reduced.

According to the embodiment as described above, the gate electrode 13 is not located at the portion Rc to avoid reducing the breakdown voltage. Therefore, as a MOSFET, the portion Rc is a dead space. According to the embodiment, the dead space is utilized as a SBD. As a result, compared with a case where a SBD part is provided separately from the MOSFET part, the area ratio of the MOSFET part in the semiconductor device 1 can be increased, and the on-resistance can be reduced.

Although an example is shown in the embodiment in which the shape of the region R when viewed from above is a square, the shape of the region R is not limited thereto. It is sufficient for the shape of the region R to be gaplessly packed; and the shape may be, for example, a polygon or a quadrilateral. The shape of the region R may be an equilateral triangle or a regular hexagon.

Although an example is shown in the embodiment in which the gate electrode 13 is continuously provided by using the portion 13x, the portion 13y, and the frame-shaped portion 13z, the configuration is not limited thereto. It is sufficient for the gate electrode 13 not to be located at the position of the region R most distant to the FP electrode 14. For example, the frame-shaped portion 13z may not be included when the portions 13x and 13y are connected to the gate pad by an upper wiring part.

Although an example is shown in the embodiment in which the source electrode 12 has a two-layer structure in which the lower layer 12a and the upper layer 12b are stacked, the structure is not limited thereto. It is sufficient for at least a portion of the source electrode 12 contacting the drift layer 22 to be formed of a material that forms a Schottky barrier junction with the drift layer 22. For example, the entire source electrode 12 may be formed of a material that forms a Schottky barrier junction with the drift layer 22.

### COMPARATIVE EXAMPLE

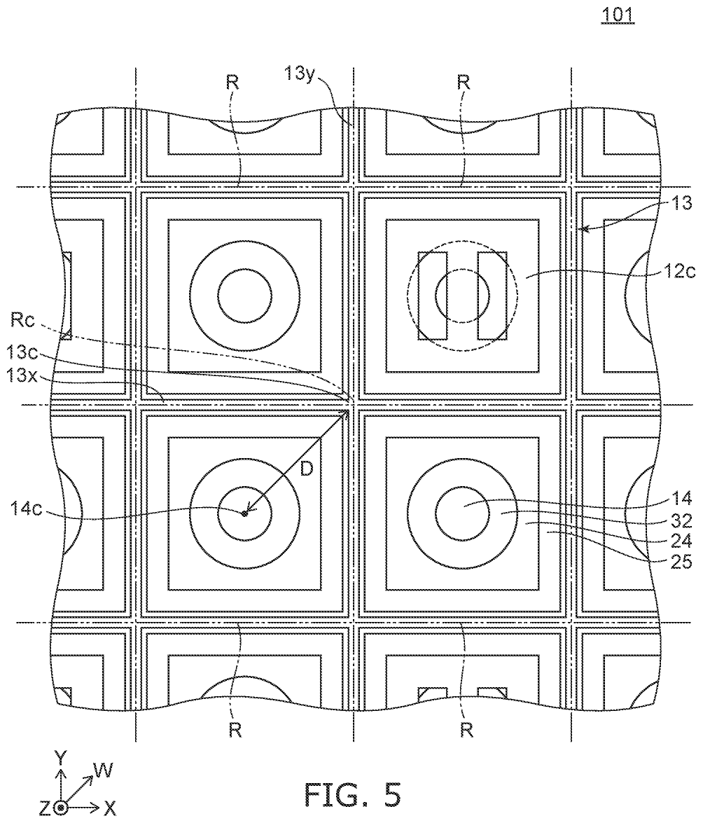

FIG. 5 is a plan view showing a semiconductor device according to the comparative example.

In the semiconductor device 101 according to the comparative example as shown in FIG. 5, the gate electrode 13 also is located at the portion Rc of the boundary of the regions R most distant to the FP electrode 14.

A distance D between a portion 13c of the gate electrode 13 located at the portion Rc and a center 14c of the FP electrode 14 is the longest distance between the gate electrode 13 and the center 14c of the FP electrode 14. Therefore, there is little effect of the FP electrode 14 relaxing the electric field concentration at the portion 13c; and the breakdown voltage is low. As a result, compared with the semiconductor device 1, the breakdown voltage of the semiconductor device 101 is low. If about the same breakdown voltage as the semiconductor device 1 were to be realized in the semiconductor device 101, it would be necessary to reduce the carrier concentration of the drift layer 22; and the on-resistance would increase.

Also, the recovery loss (Qrr) of the parasitic diode is large because the semiconductor device 101 does not include a SBD. Although a SBD part can be provided separately from the MOSFET part, in such a case, the area ratio of the MOSFET part in the semiconductor device 101 is reduced, and the on-resistance is increased.

According to the embodiments described above, a semiconductor device can be realized in which the breakdown voltage can be increased and the on-resistance can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first electrode;
a first semiconductor layer located on the first electrode, the first semiconductor layer including a plurality of regions, the first semiconductor layer being connected to the first electrode, the first semiconductor layer being of a first conductivity type;
a second semiconductor layer located on the first semiconductor layer, the second semiconductor layer being of a second conductivity type;
a third semiconductor layer located on a portion of the second semiconductor layer, the third semiconductor layer being of the first conductivity type;
a second electrode located in each of the plurality of regions, the second electrode facing the first semiconductor layer via an insulating body;
a third electrode arranged along a boundary between adjacent regions of the plurality of regions, the third electrode not being located at a portion of the boundary most distant to the second electrode, the third electrode facing the second semiconductor layer via an insulating body; and
a fourth electrode located on the third semiconductor layer, the fourth electrode being connected to the second semiconductor layer, the third semiconductor layer, and the second electrode, a portion of the fourth electrode located at the most distant portion having a Schottky barrier junction with the first semiconductor layer.

2. The device according to claim 1, wherein
a shape of the region is a polygon, and
the most distant portion is a corner of the polygon.

3. The device according to claim 1, wherein
a shape of the region is a square.

4. The device according to claim 1, further comprising:
a fourth semiconductor layer located at the most distant portion, the fourth semiconductor layer contacting the first semiconductor layer and the fourth electrode, the fourth semiconductor layer being of the second conductivity type.

5. The device according to claim 4, wherein
a plurality of the second electrodes is arranged in a matrix configuration along a first direction and a second direction orthogonal to the first direction, and
the plurality of second electrodes and the fourth semiconductor layer are alternately arranged along a third direction crossing the first and second directions.

6. The device according to claim 1, wherein
the third electrode surrounds the second electrode.

7. The device according to claim 1, wherein
the fourth electrode includes:
a first metal layer having a Schottky barrier junction with the first semiconductor layer; and
a second metal layer located on the first metal layer.

8. The device according to claim 7, wherein
the first metal layer includes at least one type of metal selected from the group consisting of titanium, nickel, platinum, and tungsten, and
the second metal layer includes at least one type of metal selected from the group consisting of aluminum and copper.
